(19) United States
(12) Patent Application Publication
(10) Pub. No.: US 2017/0238423 A1
(43) Pub. Date: Aug. 17, 2017

(54) FLEXIBLE TRANSPARENT ELECTRODE AND METHOD FOR MANUFACTURING SAME

(71) Applicant: INDUSTRY-ACADEMIC COOPERATION FOUNDATION YONSEI UNIVERSITY, Seoul (KR)

(72) Inventors: Jungho HWANG, Seoul (KR); Jaehong PARK, Seoul (KR)

(21) Appl. No.: 15/581,367

(22) Filed: Apr. 28, 2017

Related U.S. Application Data
(62) Division of application No. 14/804,906, filed on Jul. 21, 2015, now abandoned.

(51) Int. Cl. H05K 3/00; H05K 1/09; H05K 1/03; H05K 3/12

(52) U.S. Cl. CPC H05K 3/0091; H05K 3/125; H05K 1/097; H05K 1/0393; H05K 2201/0108

(57) ABSTRACT

A method for manufacturing a flexible transparent electrode includes: preparing a substrate made of a flexible and transparent material, a metal nanocolloidal solution and an electrohydrodynamic jet printing device; fixing the substrate at a position spaced apart from an injection nozzle of the electrohydrodynamic jet printing device at a predetermined interval in order to print a metal pattern on the substrate using the electrohydrodynamic jet printing device; applying AC voltage of a predetermined power to the substrate and the injection nozzle of the electrohydrodynamic jet printing device; printing the metal pattern on an upper side of the substrate by the metal nanocolloidal solution using the electrohydrodynamic jet printing device in a state where the AC voltage of the predetermined power is applied to the substrate and the injection nozzle; and sintering the metal pattern formed on the substrate.

### CROSS-REFERENCE TO RELATED APPLICATION(S)

This application is a division of U.S. patent application Ser. No. 14/804,906, filed Jul. 21, 2015, which claimed priority to Korean Patent Application No. 10-2014-0092813, filed Jul. 22, 2014, the disclosures of which are incorporated in their entireties herein by reference.

### BACKGROUND OF THE INVENTION

1. Field of the Invention

The present invention relates to a flexible transparent electrode and a method for manufacturing the same, and, more particularly, to a flexible transparent electrode and a method for manufacturing the same using electrohydrodynamic jet printing.

2. Background Art

Conventional transparent electrodes mainly use indium tin oxide (ITO). Indium tin oxide is a mixture of In₂O₃ and SnO₂, and generally has 90% of In₂O₃ and 10% of SnO₂. In general, Indium tin oxide is called “ITO”. ITO has transparency when it is manufactured into a thin film. Moreover, ITO has high electrical conductivity and optical transparency. However, such characteristics are applied only when ITO is a thin film, and if ITO exceeds a predetermined thickness, electrical conductivity increases but optical transparency decreases. The thin film of ITO may be generally deposited onto the surface by electron beam deposition, vapor deposition, or sputtering.

FIG. 1 is a perspective view of a transparent electrode according to a prior art.

As shown in FIG. 1, in case that indium tin oxide is manufactured into a thin film, ITO is utilized as a transparent electrode because having transparency and high electrical conductivity. Besides the transparent electrode shown in FIG. 1, indium tin oxide is mainly used to make transparent conductive coating in liquid crystal displays, flat panel displays, plasma displays, touch screens, electronic paper applications, organic light-emitting diodes, solar cells, antistatic coating, electromagnetic interference shielding and so on.

However, the transparent electrode using indium tin oxide according to the prior art has a problem in that manufacturing price is high because material prices of indium tin oxide are high due to limited resources of indium. Furthermore, indium tin oxide has another problem in that it is fragile because it is weak to an external force, such as flexure. Additionally, a general process to manufacture an indium tin oxide thin film is very complicated because it requires a high vacuum condition.

Due to the above-mentioned problems, studies on various materials to substitute for indium tin oxide are under way. For instance, as such materials, there are carbon nanotube (CNT), graphene, silver nanowire, and so on. However, it is hard for such materials to satisfy electrical conductivity as well as transparency.

In order to overcome the various problems, a method for manufacturing a metal mesh structure on a transparent film was proposed, and a representative example of the method is lithography which is used in the semiconductor process.

FIG. 2 is a process schematic diagram of a transparent electrode manufacturing method according to a prior art. As shown in FIG. 2, lithography means a process method for forming a pattern 24 on an upper side of a wafer 21 after moving a pattern of a mask 23 onto the wafer 21 using a sacrificial layer 22. Lithography is unfavorable in an aspect of environmental pollution because it uses special chemical substances which are dangerous and are complicated in process phases.

As another method, there is an inkjet method. The inkjet method is a direct writing method capable of patterning a mesh structure but is disadvantageous in manufacturing the transparent electrode due to a thick linewidth. In detail, in order to manufacture the transparent electrode, the pattern of the mesh structure must have a linewidth under 50 μm. However, the conventional inkjet method cannot be applied to the transparent electrode manufacturing method because it cannot embody the linewidth under 50 μm.

In other words, in the conventional inkjet method, because the size of a nozzle has an absolute influence on the size of droplets, the size of the nozzle must be reduced in proportion to the size of the size of droplets in order to spray fine droplets. However, when a nozzle of a fine size is used, there are several limitations in that nozzle clogging frequently occurs at a nozzle outlet and in that it is difficult to attach the sprayed droplets onto a designated position of the surface of the substrate owing to the Brownian movement in the air.

Nevertheless, because the inkjet printing technology has many advantages in that manufacturing costs are reduced and in that it is easy to realize a large area, technology development for solving the above-mentioned problems is on the way. In detail, in a thesis entitled ‘study on fabrication of high-resolution inkjet-printed conductive patterns assisted by soft lithography’ written by Seong Ji Soo at Hanyang University in 2013 as a dissertation, the method for producing high-solution conductive patterns using inkjet printing technology and soft lithography has been proposed.

The producing method proposed in the thesis is a method including the steps of treating SU-8 patterns made through nanoimprint with UV/O₃, forming a wettability contrast formed through microcontact printing on the surface of a substrate and forming electrode patterns using inkjet printing.

The producing method proposed in the thesis can partially solve the problems of the prior arts because it can form high-solution patterns using inkjet technology, but has a new problem in that it requires complicated processes in production. In addition, the producing method proposed in the thesis has another problem in that time required for production is long and manufacturing costs are increased because the method needs pre-treatment processes of multiple stages for inkjet printing.

Therefore, people need technology for producing a transparent electrode to which materials to substitute for the expensive indium tin oxide can be applied and which can reduce manufacturing costs because it is easily produced through a simple manufacturing process. For this, technology for utilizing an electrohydrodynamic jet printing device has been developed.

The electrohydrodynamic jet printing technology is a printing technology carrying out printing through the steps of applying high voltage a solution to provide charges and ultra-atomizing the solution having charges.

FIG. 3 is a conceptual view showing an electrohydrodynamic jet printing device according to a prior art.

Referring to FIG. 3, the electrohydrodynamic jet printing device 30 according to the prior art includes a supporter 31 moved by a computer control and a micro capillary nozzle 32 mounted above the supporter 31. Patterns are printed while fine ink drops sprayed through the nozzle 32 are attached on a substrate 33 which is moving together with the supporter 31. In this instance, printing is carried out through the steps of applying high voltage to the supporter 31 and the nozzle 32 to provide charges to a printing solution and ultra-atomizing the solution having charges.

As shown in FIG. 3, the electrohydrodynamic jet printing method according to the prior art is embodied by a pin-pin manner which always requires rounded-type, pin-type or plate-type ground electrodes below the substrate 33. Such an electrohydrodynamic jet printing technology may have a positive influence on refinement of the linewidth, but has several problems in that it has a limitation in installation and management of ground electrodes and in that it is difficult to form patterns stably because electrical influences are varied according to materials and thickness of the substrate 33.

FIG. 4 is a graph and a side view of a change of DC voltage by time to show an injection state of an injection nozzle according to application of DC voltage in case that a transparent electrode is manufactured using the electrohydrodynamic jet printing device according to the prior art. Moreover, FIG. 5 is a plan view showing the transparent electrode on which a pattern is formed by the injection nozzle shown in FIG. 4.

As shown in FIG. 4, a stream 2′ of the injected solution is bent because electrical influences are varied according to materials and thickness of the substrate 33. Furthermore, as shown in FIG. 5, printed shapes formed on the surface of the substrate 33 are irregular and incorrect. Such a phenomenon occurs by a repulsive force between solution particles because the solution injected from the injection nozzle by application of DC voltage is always charged with the same polarity. Therefore, the solution particles 2″ formed on the surface of the substrate 33 push solution particles, which are newly printed on the surface of the substrate 33, by the repulsive force, and finally, irregular pattern is formed as shown in FIG. 5.

Therefore, also the transparent electrode manufacturing method using the electrohydrodynamic jet printing technology according to the prior art cannot obtain a stable pattern.

### SUMMARY OF THE INVENTION

Accordingly, the present invention has been made to solve the above-mentioned problems occurring in the prior arts, and it is an object of the present invention to provide a flexible transparent electrode and a method for manufacturing the same which can apply DC voltage without any influence of an electric field and form a pattern of a mesh structure because droplets charged equally are attached onto a substrate when voltage is applied to an object to be printed and an injection nozzle using an electrohydrodynamic jet printing device, thereby easily manufacturing a flexible transparent electrode.

To accomplish the above object, according to the present invention, there is provided a flexible transparent electrode including: a substrate made of a flexible and transparent material; and a metal pattern which is formed on the substrate in a mesh form and has an electroconductive metal material, wherein the metal pattern is formed by being patterned on an upper side of the substrate using an electrohydrodynamic jet printing method and being sintered, and the electrohydrodynamic jet printing method is a method of forming a metal pattern on the upper side of the substrate after applying AC voltage of a predetermined power to the substrate and an injection nozzle of an electrohydrodynamic jet printing device.

In this instance, the material of the substrate is at least one selected from groups comprised of polyethylene naphthalate (EN), polycarbonate (PC), polyethersulfone (PES), polyarylate (PAR), polysulfone (PSF), cyclic-olefin copolymer (COC), polyimide (PI), PI-fluoro-based high molecular compound, polyetherimide (PEI) and epoxy resin.

In an embodiment, the electroconductive metal material of the metal pattern is at least one selected from groups comprised of silver (Ag), gold (Au), copper (Cu), aluminum (Al) and iron (Fe).

Moreover, the metal pattern has a structure that at least two squares are arranged to adjoin each other.

Furthermore, the metal pattern has a structure that a structure that at least two polygons are arranged to adjoin each other.

In an embodiment, the linewidth (w) of the metal pattern is within a range of 1 μm to 30 μm.

Additionally, a distance (p) between lines of the metal pattern is in a range of 200 μm to 1,000 μm.

In an embodiment, an injection cycle of the injection nozzle of the electrohydrodynamic jet printing device and an AC cycle are in integer multiple relationship with each other, and the injection nozzle carries out injection at the highest voltage or the lowest voltage of AC voltage.

In another aspect of the present invention, there is provided a transparent electrode manufacturing method including: a) a preparation step of preparing a substrate made of a flexible and transparent material, a metal nanocolloidal solution and an electrohydrodynamic jet printing device; b) a substrate fixing step of fixing the substrate at a position spaced apart from an injection nozzle of the electrohydrodynamic jet printing device at a predetermined interval in order to print a metal pattern on the substrate using the electrohydrodynamic jet printing device; c) an AC voltage applying step of applying AC voltage of a predetermined power to the substrate and the injection nozzle of the electrohydrodynamic jet printing device; d) a pattern forming step of printing the metal pattern on an upper side of the substrate by the metal nanocolloidal solution using the electrohydrodynamic jet printing device in a state where the AC voltage of the predetermined power is applied to the substrate and the injection nozzle; and e) a pattern sintering step of sintering the metal pattern formed on the substrate.

In this instance, the material for the metal nanoparticles forming the metal nanocolloidal solution is at least one selected from groups comprised of silver (Ag), gold (Au), copper (Cu), aluminum (Al) and iron (Fe).

In an embodiment, the pattern forming step includes the steps of: d-1) controlling the power of AC voltage; d-2) controlling injection pressure of the injection nozzle; d-3) controlling a distance between the injection nozzle and the substrate; and d-4) moving a flat position of the substrate according to the preset form of the metal pattern.

Moreover, in the pattern forming step, an injection cycle of the injection nozzle of the electrohydrodynamic jet printing device and an AC cycle are in integer multiple relationship with each other, and the injection nozzle carries out injection at the highest voltage or the lowest voltage of AC voltage.

In an embodiment, in the pattern sintering step, sintering temperature is 170° C. to 190° C. and a sintering period is 15 minutes to 25 minutes.

In a further aspect of the present invention, there is provided a transparent electrode manufacturing apparatus including: an electrohydrodynamic jet printing device having a fixing unit for fixing a substrate and an injection nozzle for printing a pattern on the substrate fixed on the fixing unit; an AC voltage supplier for applying AC voltage of a predetermined power to the fixing unit and the injection nozzle; a driving unit for changing a flat position of the fixing unit according to a preset form of a metal pattern; and a control unit for controlling the electrohydrodynamic jet printing device, the AC voltage supplier and the driving unit.

In an embodiment, the transparent electrode manufacturing apparatus further includes a camera which monitors the state of the metal pattern printed on the substrate by the electrohydrodynamic jet printing device.

In addition, the present invention provides an electronic apparatus of a flexible structure including the transparent electrode.

As described above, the transparent electrode according to the present invention can reduce manufacturing costs because it can be manufactured utilizing a high molecular compound or resin which is more inexpensive than the prior arts.

Moreover, the transparent electrode according to the present invention provides a pattern with a linewidth thinner than that of the prior arts, thereby enhancing transparency.

Furthermore, the transparent electrode manufacturing method according to the present invention can manufacture a transparent electrode through the more simplified process than the prior arts because using the electrohydrodynamic jet printing method by applying AC voltage to a flexible and high dielectric material like a PET film.

Additionally, the transparent electrode manufacturing method according to the embodiment of the present invention can manufacture a transparent electrode having a pattern with a thinner linewidth than that of the prior art because using the electrohydrodynamic jet printing method.

Furthermore, the transparent electrode manufacturing method according to the embodiment of the present invention can manufacture a transparent electrode utilizing a high molecular compound or resin which is more inexpensive compared with the prior arts and manufacture a transparent electrode by more simplified processes compared with the prior arts, thereby reducing manufacturing costs.

In addition, the transparent electrode manufacturing method according to the embodiment of the present invention is safe and does not cause environmental pollution because not using special chemical substances which are dangerous.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a perspective view of a transparent electrode according to a prior art;

FIG. 2 is a process schematic diagram of a transparent electrode manufacturing method according to a prior art;

FIG. 3 is a conceptual view showing an electrohydrodynamic jet printing device according to a prior art;

FIG. 4 is a graph and a side view of a change of DC voltage by time to show an injection state of an injection nozzle according to application of DC voltage in case that a transparent electrode is manufactured using the electrohydrodynamic jet printing device according to the prior art;

FIG. 5 is a plan view showing a transparent electrode on which a pattern is formed by the injection nozzle shown in FIG. 4;

FIG. 6 is a perspective view of a transparent electrode according to the present invention;

FIG. 7 is a plan view of the transparent electrode shown in FIG. 6;

FIG. 8 is a partially enlarged view of the part “A” of FIG. 7;

FIGS. 9 and 10 are views of a metal pattern forming the transparent electrode according to another embodiment of the present invention;

FIG. 11 is a conceptual view of a transparent electrode manufacturing apparatus according to the present invention;

FIG. 12 is a perspective view showing a metal pattern formed by an electrohydrodynamic jet printing device shown in FIG. 11;

FIG. 13 is a partially enlarged view of the part “B” of FIG. 12;

FIG. 14 is a flow chart showing a transparent electrode manufacturing method according to the present invention;

FIG. 15 is a flow chart showing a pattern forming steps of FIG. 14;

FIG. 16 is a graph and a side view of a change of AC voltage by time to show an injection state of an injection nozzle according to application of AC voltage in case that a transparent electrode is manufactured using the transparent electrode manufacturing apparatus according to the present invention;

FIG. 17 is a plan view showing a transparent electrode on which a pattern is formed by the injection nozzle shown in FIG. 16;

FIG. 18 is a photograph showing an image that a light-emitting diode emits light using the flexible transparent electrode according to the present invention;

FIG. 19 is a graph showing a transmittance ratio changed according to the wavelengths of transmitted light sources by filling factor values;

FIG. 20 is a graph showing a resistance value of the transparent electrode changed according to the filling factor values by sintering temperature; and

FIG. 21 is a graph showing a resistance value of the transparent electrode changed according to repeated bending cycles by materials of metal patterns.

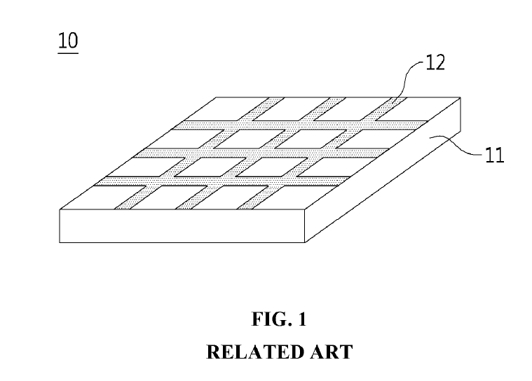

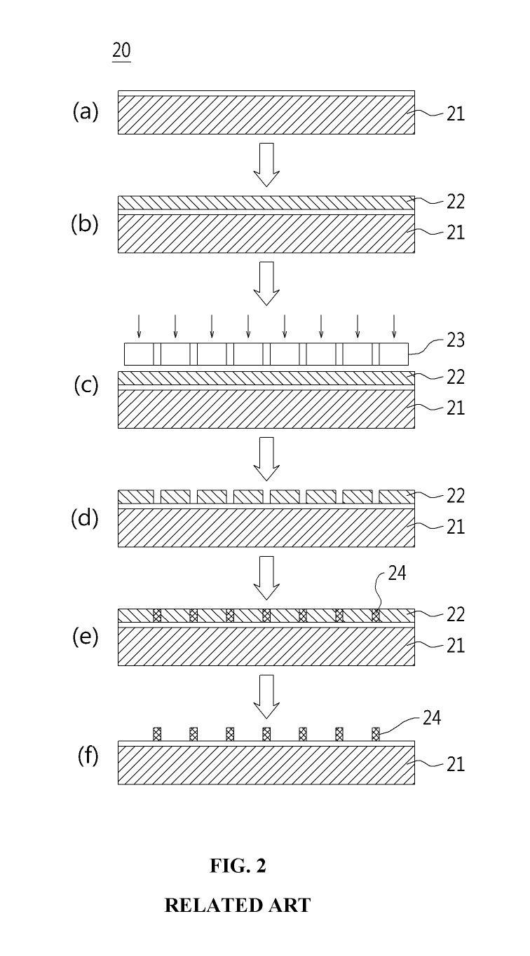

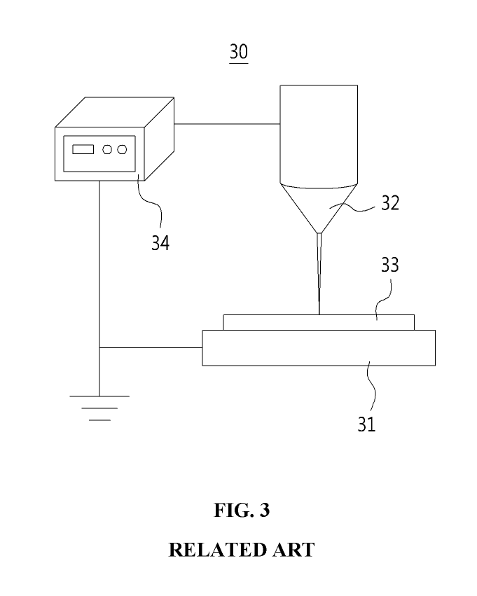

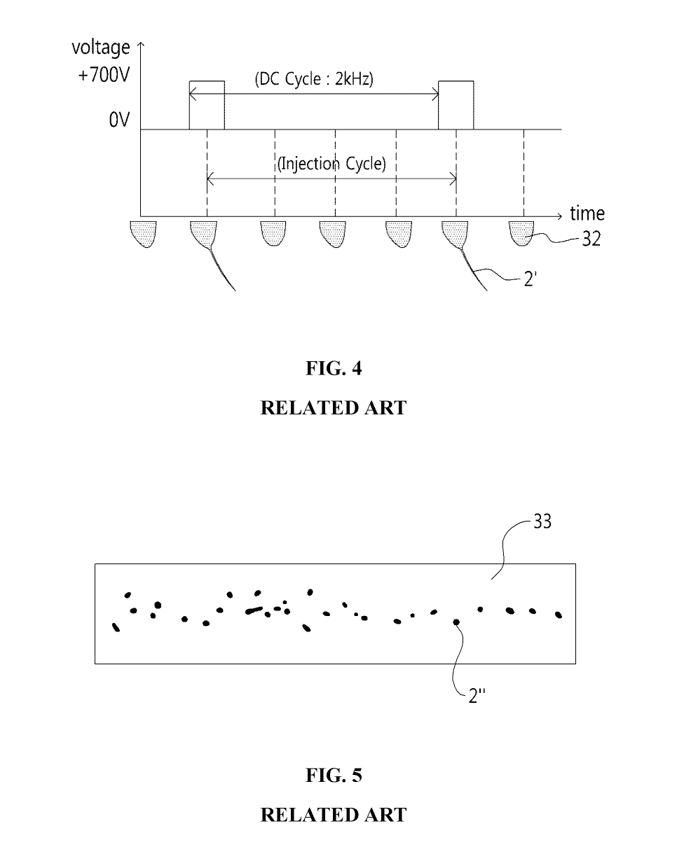

### DETAILED DESCRIPTION OF THE PREFERRED EMBODIMENT

Hereinafter, reference will be now made in detail to the preferred embodiments of the present invention with reference to the attached drawings, but the scope of the present invention is not limited by the attached drawings and embodiments. In addition, in the description of the present invention, when it is judged that detailed descriptions of known functions or structures related with the present invention may make the essential points vague, the detailed descriptions of the known functions or structures will be omitted.

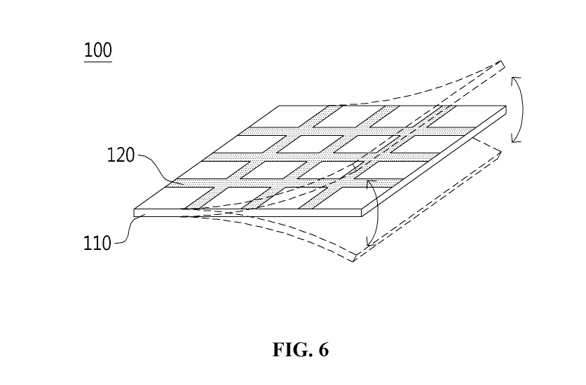

FIG. 6 is a perspective view of a transparent electrode according to the present invention.

Referring to FIG. 6, the transparent electrode 100 according to an embodiment of the present invention is a flexible transparent electrode, and includes a substrate 110 made of a flexible and transparent material and a metal pattern 120 which is formed on the substrate 110 in a mesh form and has an electroconductive metal material.

In this instance, the metal pattern 120 formed on the upper side of the substrate 110 may be manufactured by being sintered after being patterned on the upper side of the substrate 110 using the electrohydrodynamic jet printing method. Here, the electrohydrodynamic jet printing method will be described in detail later.

The material which is applicable to the substrate 110 according to the present invention is not limited if it is a transparent and flexible material. For instance, the material may be polyethylene terephthalate (PET). Additionally, the material which is applicable to the substrate 110 may be at least one selected from groups comprised of polyethylene naphthalate (EN), polycarbonate (PC), polyethersulfone (PES), polyarylate (PAR), polysulfone (PSF), cyclic-olefin copolymer (COC), polyimide (PI), PI-fluoro-based high molecular compound, polyetherimide (PEI) and epoxy resin.

In addition, the electroconductive metal material which forms the metal pattern 120 formed on the upper side of the substrate 110 may be silver (Ag). The electroconductive metal material is prepared in a colloidal solution state, and then, is formed on the upper side of the substrate 110 by the electrohydrodynamic jet printing method. Preferably, the electroconductive metal material is silver (Ag), but may be formed on the upper side of the substrate 110 by the electrohydrodynamic jet printing method and may be substituted with any electroconductive material. For instance, the electroconductive metal material may be at least one selected from groups comprised of silver (Ag), gold (Au), copper (Cu), aluminum (Al) and iron (Fe). Here, the electrohydrodynamic jet printing method will be described in detail later.

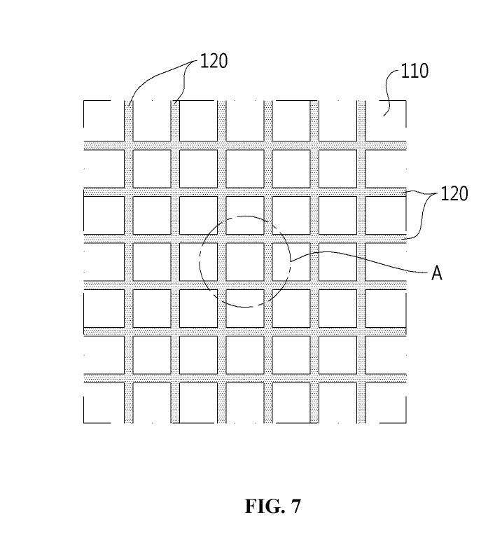

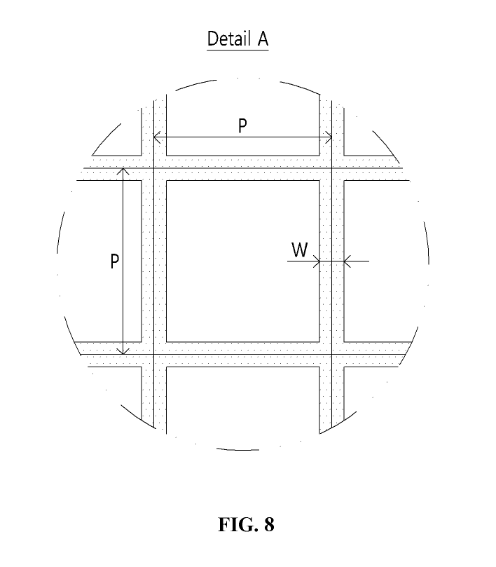

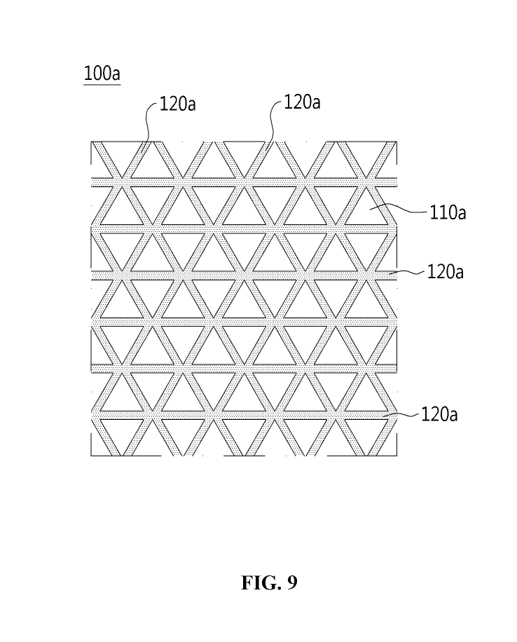

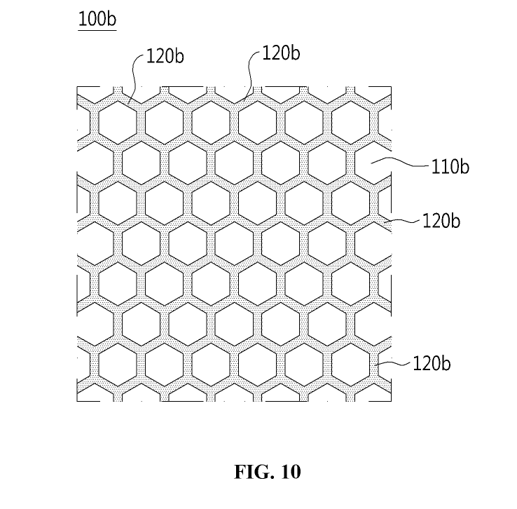

FIG. 7 is a plan view of the transparent electrode shown in FIG. 6, FIG. 8 is a partially enlarged view of the part “A” of FIG. 7, and FIGS. 9 and 10 are views of a metal pattern forming the transparent electrode according to another embodiment of the present invention.

Referring to the drawings, the metal pattern 120 formed on the upper side of the substrate 110 may have a mesh structure. As shown in FIG. 7, the mesh structure has a plurality of vertical lines and a plurality of horizontal lines which are spaced apart from each other at regular intervals. That is, as shown in FIGS. 7, 9 and 10, the mesh structure may be a structure that at least two squares, equilateral triangles or polygons are arranged to adjoin each other. The mesh structure of the metal pattern 120 is not restricted to the above, and of course, may be properly varied according to a designer's intention.

In the meantime, referring to FIG. 8, the linewidth (w) of the metal pattern 120 is not limited if it does not considerably reduce transmittance and electroconductivity of the transparent electrode, but, preferably, is in a range of 1 μm to 30 μm. Moreover, a distance between lines of the metal pattern 120 is not limited if it does not considerably reduce transmittance and electroconductivity of the transparent electrode, but, preferably, is in a range of 200 μm to 1,000 μm.

In order to quantifiably indicate an area ratio of the metal pattern 120 formed on the upper side of the substrate 110, the filling factor (FF) may be defined as follows:

$$FF = \frac{( pSw ) + [ ( p - w ) Sw ]}{{p}^{2}} \qquad ( Equation 1 )$$

In the equation 1, the filling factor (FF) is a value showing the area ratio to form the metal pattern 120 contrast to the area of the substrate 110, p is a linewidth of the metal pattern 120, and w is a distance between the lines of the metal pattern 120.

As shown in the equation 1, the area of the metal pattern 120 formed on the upper side of the substrate 110 is increased as the FF value increases. Of course, the FF value is not limited if it does not considerably reduce transmittance and electroconductivity of the transparent electrode, but, preferably, is less than 0.3, and more preferably, less than 0.07.

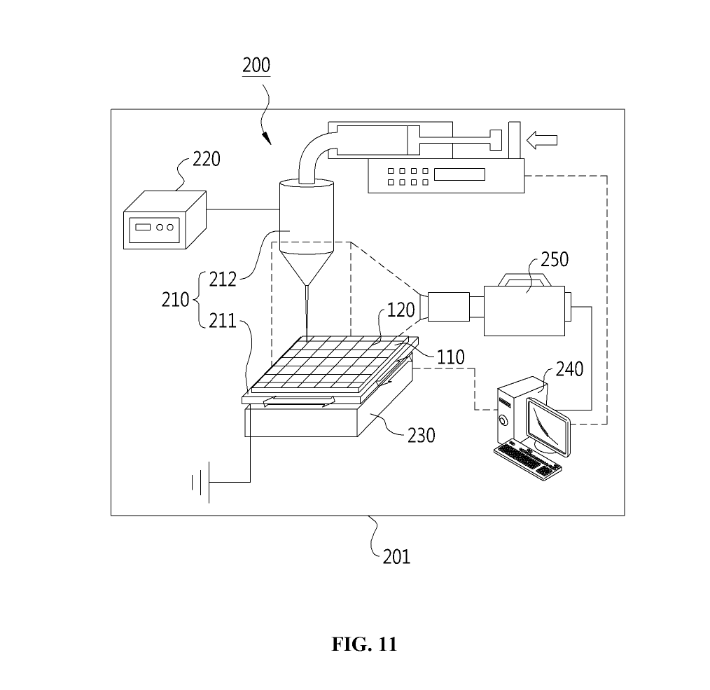

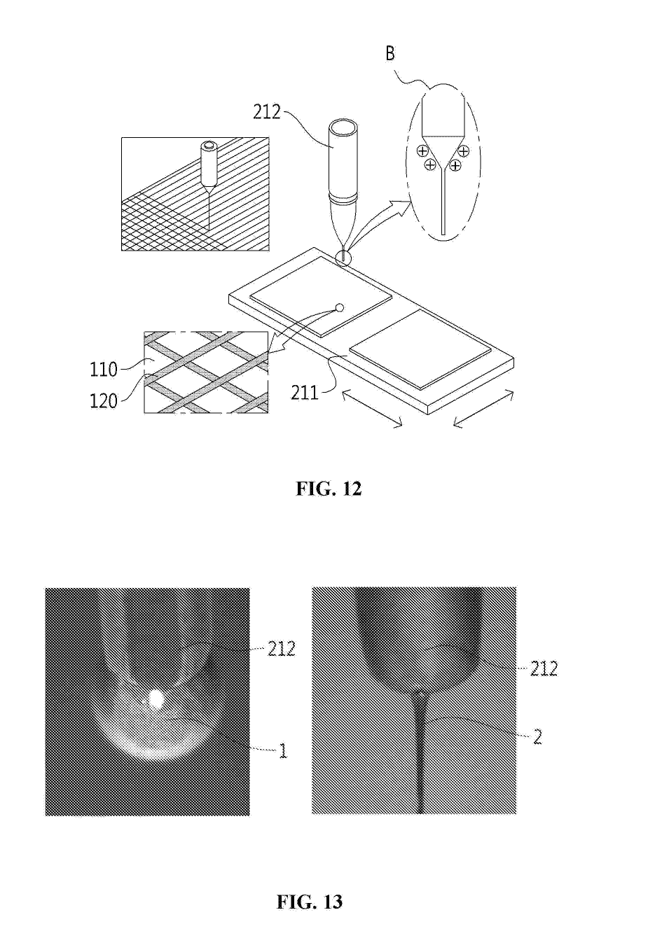

FIG. 11 is a conceptual view of a transparent electrode manufacturing apparatus according to the present invention, FIG. 12 is a perspective view showing a metal pattern formed by an electrohydrodynamic jet printing device shown in FIG. 11, and FIG. 13 is a partially enlarged view of the part “B” of FIG. 12.

Referring to FIG. 11, the transparent electrode manufacturing apparatus 200 according to the embodiment of the present invention includes an electrohydrodynamic jet printing device 210, an AC voltage supplier 220, a driving unit 230 and a control unit 240.

In detail, the electrohydrodynamic jet printing device 210 is a device applying an electrohydrodynamic spray technology to ultra-atomize a solution having charges after providing charges by applying high voltage. The electrohydrodynamic jet printing can electrically carry out the preconditioning process before printing after conveying lots of ink toward an object to be sprayed, remarkably enhance resolution of nano-scale compared with the conventional inkjet printing method because it is capable of applying a flow of an electrically induced fluid to a nano-scale nozzle, and control a printed state in a new way to control electrically.

In general, as shown in FIG. 11, the electrohydrodynamic jet printing device 210 may include a driving unit 230 and a fixing unit 211 moved by the control unit 240, and an injection nozzle 212 which is spaced apart from the fixing unit 211 at a predetermined interval. Moreover, as shown in FIGS. 12 and 13, a metal nanocolloidal droplet 1 injected through the injection nozzle 212 is attached onto the upper side of the substrate 110 to print the pattern 120 while moving.

Furthermore, the AC voltage supplier 220 can apply AC voltage of a predetermined size to the fixing part 211 and the injection nozzle 212, and the control unit 240 controls the electrohydrodynamic jet printing device 210, the AC voltage supplier 220 and the driving unit 230.

According to circumstances, as shown in FIG. 11, the transparent electrode manufacturing apparatus 200 according to the embodiment of the present invention may further include a camera 250 which monitors the state of the metal pattern 120 printed on the substrate 110 by the electrohydrodynamic jet printing device 210.

Additionally, it is preferable that the transparent electrode manufacturing apparatus 200 according to the embodiment of the present invention be installed and managed inside a class-100 clean room 201.

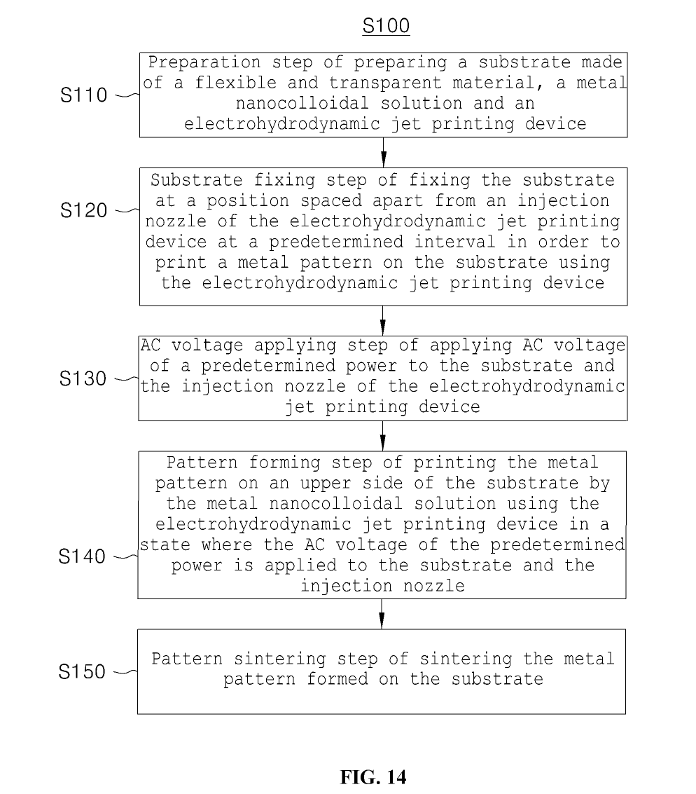

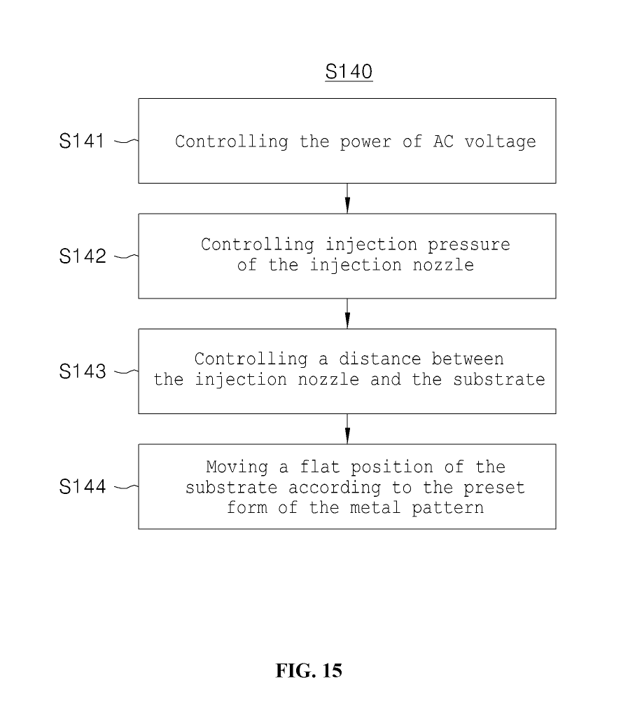

FIG. 14 is a flow chart showing a transparent electrode manufacturing method according to an embodiment of the present invention, and FIG. 15 is a flow chart showing a pattern forming steps of FIG. 14.

Referring the drawings together with FIG. 11, the transparent electrode manufacturing method (S100) according to the embodiment of the present invention includes a preparation step (S110) of preparing a substrate 110 made of a flexible and transparent material, a metal nanocolloidal solution and an electrohydrodynamic jet printing device 210.

In this instance, the substrate 110 made of the flexible and transparent material may be at least one selected from groups comprised of polyethylene naphthalate (EN), polycarbonate (PC), polyethersulfone (PES), polyarylate (PAR), polysulfone (PSF), cyclic-olefin copolymer (COC), polyimide (PI), PI-fluoro-based high molecular compound, polyetherimide (PEI) and epoxy resin. In addition, the material for the metal nanoparticles forming the metal nanocolloidal solution may be at least one selected from groups comprised of silver (Ag), gold (Au), copper (Cu), aluminum (Al) and iron (Fe).

Moreover, as shown in FIG. 8, the electrohydrodynamic jet printing device 210 is a device applying the electrohydrodynamic spray technology, and a detailed description of the device will be omitted because it is described above.

The transparent electrode manufacturing method (S100) according to the embodiment of the present invention includes a substrate fixing step (S120) of fixing the substrate 211 at a position spaced apart from the injection nozzle 212 of the electrohydrodynamic jet printing device 210 at a predetermined interval in order to print the metal pattern 120 on the substrate 110 using the electrohydrodynamic jet printing device 210.

Furthermore, the transparent electrode manufacturing method (S100) according to the embodiment of the present invention includes an AC voltage applying step (S130) of applying AC voltage of a predetermined power to the substrate 211 and the injection nozzle 212 of the electrohydrodynamic jet printing device 210; and a pattern forming step (S140) of printing the metal pattern 120 on the upper side of the substrate 110 by the metal nanocolloidal solution using the electrohydrodynamic jet printing device 210 in a state where the AC voltage of the predetermined power is applied to the substrate 110 and the injection nozzle 212.

In detail, the injection nozzle 212 to which AC voltage is applied induces a sprayed flow of the metal nanocolloidal solution electrically so as to stably print the pattern on the upper side of the substrate 110.

Additionally, as shown in FIG. 12, the pattern forming step (S140) includes: the steps of controlling the power of AC voltage (S141); controlling injection pressure of the injection nozzle 212 (S142); controlling a distance between the injection nozzle 212 and the substrate 110 (S143); and moving a flat position of the substrate 110 according to the preset form of the metal pattern (S144). The order of the steps of the pattern forming step (S140) may be changed and at least two steps may be carried out at the same time. In addition, of course, one or more steps of the steps may be omitted according to a user's intention.

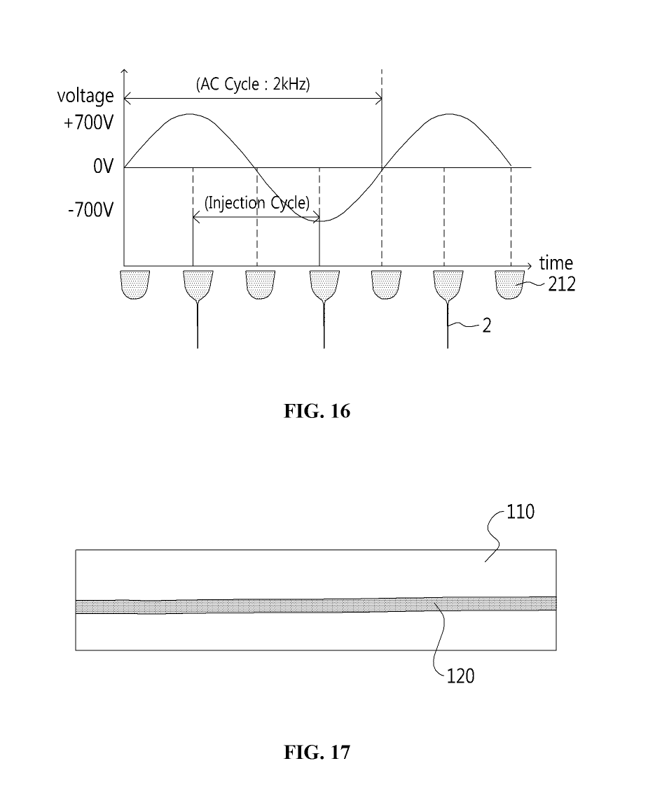

FIG. 16 is a graph and a side view of a change of AC voltage by time to show an injection state of an injection nozzle according to application of AC voltage in case that a transparent electrode is manufactured using the transparent electrode manufacturing apparatus according to the present invention, and FIG. 17 is a plan view showing a transparent electrode on which a pattern is formed by the injection nozzle shown in FIG. 16.

Referring to the drawings, the transparent electrode manufacturing method (S100) will be described continuously.

The transparent electrode manufacturing method (S100) according to the embodiment of the present invention applies AC voltage of a predetermined power to the substrate 211 and the injection nozzle 212 of the electrohydrodynamic jet printing device 210.

In case that AC voltage of the predetermined power is applied to the substrate 211 and the injection nozzle 212 of the electrohydrodynamic jet printing device 210 in order to print a pattern, as shown in FIG. 17, the pattern aligned in a row as a user intended can be obtained. Because the metal nanocolloidal droplets charged into positive or negative polarity are cyclically repeat to be attached onto the upper side of the substrate 110 when AC voltage is applied, charges of the metal nanocolloidal droplets accumulated on the substrate 110 are neutralized, and hence, it makes stable printing of the pattern 120 possible.

Furthermore, in order to print the pattern more stably, as shown in FIG. 16, an injection cycle of the injection nozzle 212 and an AC cycle are in integer multiple relationship with each other, and the injection nozzle 212 may carry out injection at the highest voltage or the lowest voltage of AC voltage.

Through a series of the steps described above, the metal pattern 120 is printed on the upper side of the substrate 110, and then, manufacturing of the transparent electrode 110 is finally completed through a pattern sintering step (S150) of sintering the metal pattern 120 formed on the substrate 110. In this instance, in the pattern sintering step (S150), sintering temperature is 170° C. to 190° C. and a sintering period is 15 minutes to 25 minutes. Of course, the sintering temperature and the sintering period can be properly changed according to the design of the transparent electrode and the user's management.

Here, the sintering process is a method that metal powder particles become lumpy into one through a thermal activation process in the metallurgy. Because sintering is a well-known method in the metallurgy, its detailed description will be omitted.

As described above, the transparent electrode manufacturing method according to the embodiment of the present invention can manufacture a transparent electrode having a pattern with a thinner linewidth than that of the prior art because using the electrohydrodynamic jet printing method. Furthermore, the transparent electrode manufacturing method according to the embodiment of the present invention can manufacture a transparent electrode utilizing a high molecular compound or resin which is more inexpensive compared with the prior arts and manufacture a transparent electrode by more simplified processes compared with the prior arts, thereby reducing manufacturing costs. Additionally, the transparent electrode manufacturing method according to the embodiment of the present invention is safe and does not cause environmental pollution because not using special chemical substances which are dangerous.

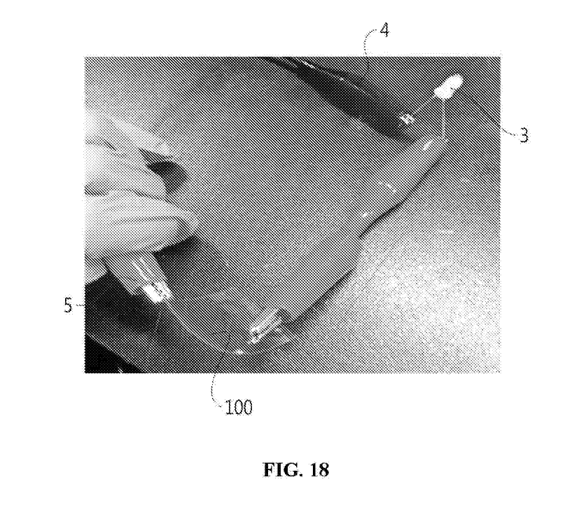

FIG. 18 is a photograph showing an image that a light-emitting diode emits light using the flexible transparent electrode according to the present invention.

As shown in FIG. 18, the transparent electrode 100 according to the present invention is flexible and transparent and has electroconductivity.

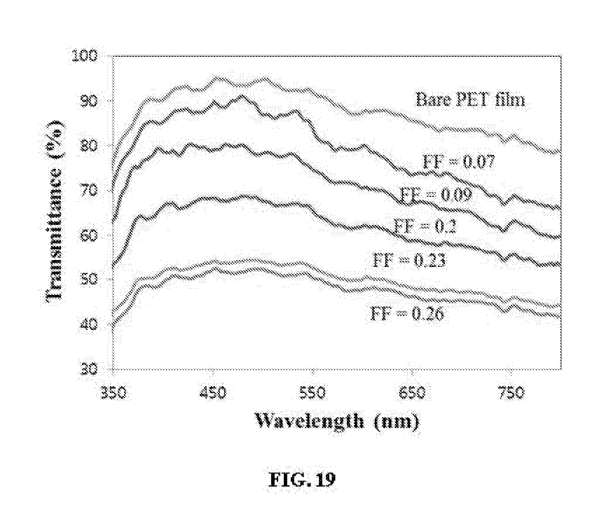

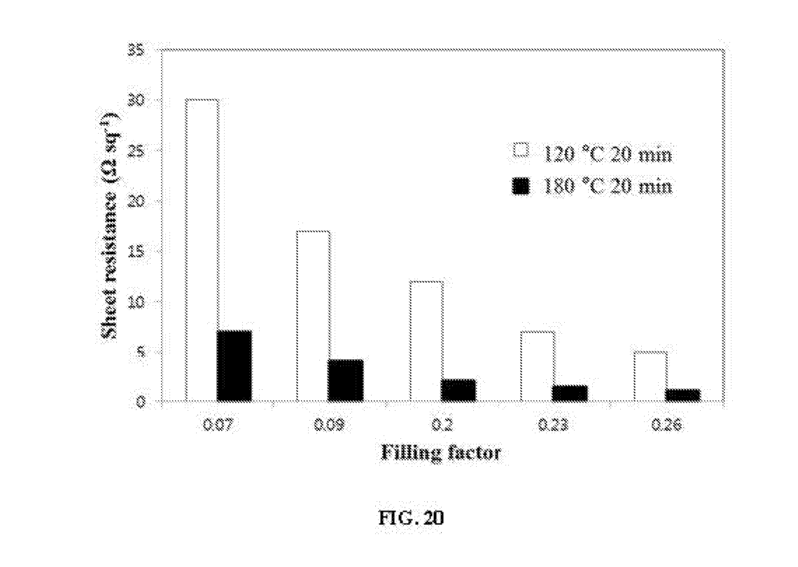

FIG. 19 is a graph showing a transmittance ratio changed according to the wavelengths of transmitted light sources by filling factor (FF) values.

Referring to FIG. 19, as described above, the FF value is defined as shown in the formula 1 in order to quantifiably indicate an area ratio of the metal pattern 120 formed on the upper side of the substrate 110.

As shown in FIG. 19, if the FF value is less than 0.07, high transmittance more than 70% is shown. Moreover, if the FF value is 0.26, transmittance in the range of 40% to 50% is shown.

FIG. 20 is a graph showing a resistance value of the transparent electrode changed according to the filling factor (FF) values by sintering temperature.

Referring to FIG. 20, if the sintering temperature is set to 120° C. in the patterning sintering step, the resistance value of the transparent electrode remarkably increases compared with the case that the sintering temperature is set to 180° C. Additionally, the resistance value of the transparent electrode is decreased as the FF value increases, and a difference between the resistance value at the sintering temperature of 120° C. and the resistance value at the sintering temperature of 180° C. is gradually reduced as the FF value increases.

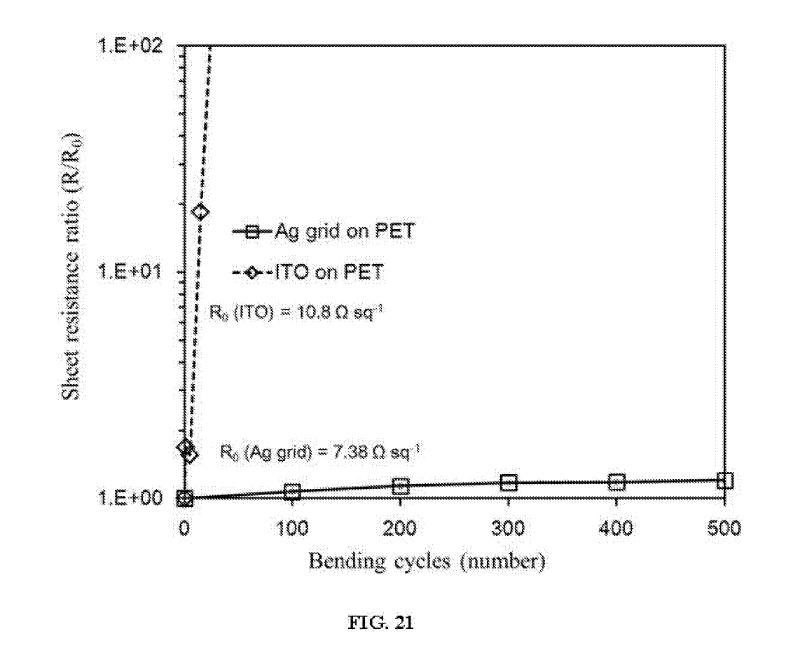

FIG. 21 is a graph showing a resistance value of the transparent electrode changed according to repeated bending cycles by materials of metal patterns.

Referring to FIG. 21, a graph of the transparent electrode according to the prior art to which ITO is applied as the metal pattern is marked with the dotted line, and a graph of the transparent electrode according to the present invention to which silver (Ag) is applied as the metal pattern is marked with the solid line.

As shown in FIG. 21, the transparent electrode according to the prior art shows that the resistance value of the transparent electrode was remarkably increased by just 30 flexural tests. On the contrary, the transparent electrode according to the present invention kept the resistance value of the uniform level even by 200 to 500 flexural tests.

As described above, while the present invention has been particularly shown and described with reference to the preferable embodiment thereof, it will be understood by those of ordinary skill in the art that the present invention is not limited to the above embodiment and that various changes, modifications and equivalences may be made therein without departing from the spirit and scope of the present invention as defined by the following claims.

What is claimed is:

1. A transparent electrode manufacturing method comprising:
a) a preparation step (S110) of preparing a substrate made of a flexible and transparent material, a metal nanocolloidal solution and an electrohydrodynamic jet printing device;
b) a substrate fixing step (S120) of fixing the substrate at a position spaced apart from an injection nozzle of the electrohydrodynamic jet printing device at a predetermined interval in order to print a metal pattern on the substrate using the electrohydrodynamic jet printing device;
c) an AC voltage applying step (S130) of applying AC voltage of a predetermined power to the substrate and the injection nozzle of the electrohydrodynamic jet printing device;
d) a pattern forming step (S140) of printing the metal pattern on an upper side of the substrate by the metal nanocolloidal solution using the electrohydrodynamic jet printing device in a state where the AC voltage of the predetermined power is applied to the substrate and the injection nozzle; and
e) a pattern sintering step (S150) of sintering the metal pattern formed on the substrate,
wherein in the pattern forming step (S140), an injection cycle of the injection nozzle of the electrohydrodynamic jet printing device and an AC cycle are in integer multiple relationship with each other, and the injection nozzle carries out injection at the highest voltage or the lowest voltage of AC voltage.

2. The transparent electrode manufacturing method according to claim 1, wherein the material for the metal nanoparticles forming the metal nanocolloidal solution is at least one selected from groups comprised of silver (Ag), gold (Au), copper (Cu), aluminum (Al) and iron (Fe).

3. The transparent electrode manufacturing method according to claim 1, wherein the pattern forming step (S140) comprises the steps of:
d-1) controlling the power of AC voltage (S141);
d-2) controlling injection pressure of the injection nozzle (S142);
d-3) controlling a distance between the injection nozzle and the substrate (S143); and
d-4) moving a flat position of the substrate according to the preset form of the metal pattern (S144).

4. The transparent electrode manufacturing method according to claim 1, wherein in the pattern sintering step (S150), sintering temperature is 170° C. to 190° C. and a sintering period is 15 minutes to 25 minutes.
